(19) United States
(12) Patent Application Publication
(10) Pub. No.: US 2006/0065983 A1
(43) Pub. Date: Mar. 30, 2006

(54) Semiconductor package with wire bond arrangement to reduce cross talk for high speed circuits

(75) Inventors: Chok J. Chia, Cupertino, CA (US); Wee Keong Liew, San Jose, CA (US); Seng Sooi Lim, San Jose, CA (US)

Correspondence Address: LSI LOGIC CORPORATION, 1621 BARBER LANE, MS: D-106, MILPITAS, CA, 95035, US

(73) Assignee: LSI Logic Corporation, Milpitas, CA (US)

(21) Appl. No.: 10/956,656

(22) Filed: Sep. 30, 2004

(51) Int. Cl. H01L 23/52

(52) U.S. Cl. 257/782

(57) ABSTRACT

A package for reducing signal cross talk between wire bonds of semiconductor packages. The package includes a semiconductor die having a plurality of bond pads formed thereon. The bond pads arranged in a first subset of bond pads and a second subset of bond pads. The package also includes a substrate having a plurality of contact points, the plurality of contact points are arranged in a first subset of contact points and a second subset of contact points. To reduce signal cross talk, the wire bonds are arranged such that a first subset of wire bonds are electrically coupled between the first subset of bond pads and the first subset of the contact points. The first subset of wire bonds have ball bonds formed on the first subset of bond pads and stitch bonds formed on the first subset of contact points respectively. A second subset of wire bonds are electrically coupled between the second subset of bond pads and the second subset of the contact points. The second subset of wire bonds have stitch bonds formed on the first subset of bond pads and ball bonds formed on the first subset of contact points respectively. The different height profiles of the first set and the second set of wire bonds tends to reduce signal cross talk between the wires.

### BACKGROUND OF THE INVENTION

1. Field of the Invention

The present invention relates generally to semiconductor packaging, and more particularly, to a semiconductor package with a wire bond arrangement to reduce cross talk between the wires.

2. Description of the Related Art

Advances in processing technology has allowed engineers to fabricate smaller and smaller transistors. The smaller transistors not only operate at faster speeds, but they also enable more and more transistors to be fabricated on a semiconductor die of a given size. This increased circuit density has enabled circuit designers to add greater functionality with each new generation of chips. The new functionality, however, increases the need for a greater number of signal inputs as well as power and ground inputs to the device. State of the art chip packages currently have hundreds and in some instances thousands of input-output pins. The increased number of input-output pins results in the bond pads on the die and the bond fingers or leads of the leadframe package to have a finer pitch. Consequently, wire bonds are spaced very close to one another on the packaged die. The closeness of the wires may create a problem. Namely, coupling noise and cross talk between the wires may cause false signal transitions on the signal input-output pins, causing the device to fail. The faster switching speeds of the transistors further exasperates this problem.

A number of approaches are known to reduce the coupling noise and cross talk problem with wire bonds of semiconductor packages. One conventional approach is to use wire bonds of different heights and loop profiles to reduce the cross talk and coupling noise between the wires. Another technique is to convert a significant number of signal bond pads into either ground (VSS) or power (VDD) pads. The spacing of either VSS or VDD pads between signal pads provides electrical shielding, isolating the adjacent signal and clock wires from coupling noise and cross talk. The problem with this approach is that it reduces the total number of usable signal input-output pins on the package.

Accordingly, there is a need for a semiconductor package with a wire bond arrangement to reduce cross talk between the wires.

### SUMMARY OF THE INVENTION

The present invention relates to a semiconductor package for reducing signal cross talk between wire bonds of a semiconductor packages. The package includes a semiconductor die having a plurality of bond pads formed thereon. The bond pads are arranged in a first subset of bond pads and a second subset of bond pads. The package also includes a substrate having a plurality of contact points, the plurality of contact points are arranged in a first subset of contact points and a second subset of contact points. To reduce signal cross talk, the wire bonds are arranged such that a first subset of wire bonds are electrically coupled between the first subset of bond pads and the first subset of the contact points. The first subset of wire bonds have ball bonds formed on the first subset of bond pads and stitch bonds formed on the first subset of contact points respectively. A second subset of wire bonds are electrically coupled between the second subset of bond pads and the second subset of the contact points. The second subset of wire bonds have stitch bonds formed on the first subset of bond pads and ball bonds formed on the first subset of contact points respectively. The different height profiles of the first set and the second set of wire bonds tends to reduce signal cross talk between the wires.

### BRIEF DESCRIPTION OF THE DRAWINGS

The invention, together with further advantages thereof, may best be understood by reference to the following description taken in conjunction with the accompanying drawings in which:

FIG. 1 is a cross section of a semiconductor package of the present invention.

FIG. 2 is a top view of the semiconductor package of the present invention.

In the figures, like reference numbers refer to like components and elements.

### DETAILED DESCRIPTION OF THE INVENTION

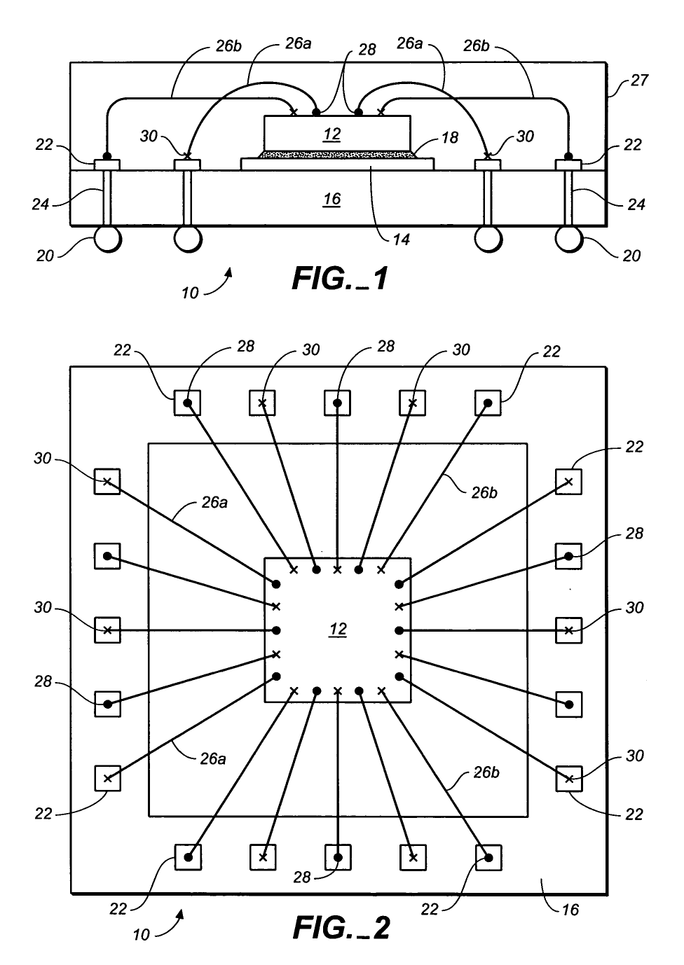

Referring to FIG. 1, a cross section of a package of the present invention is shown. The package 10 includes a semiconductor die 12 mounted onto a die attach area 14 of a substrate 16. A die attach material 18, such as an epoxy, is used to attach the die 12 to the die attach area 14. A plurality of solder ball contacts 20 are formed on the bottom surface of the substrate 16. The solder ball contacts 20 are electrically coupled to a plurality of contact points 22 on the top surface of the substrate 16 through vias 24. Although not visible in FIG. 1, the die 12 has a plurality of bond pads formed on the upper or active surface. Wire bonds 26 are formed between the bond pads on the die 12 and the contact points 22 on the substrate 16. The package is encapsulated in an encapsulant material 27.

In accordance with the present invention, the wire bonds 26 are arranged in a first subset 26a and a second subset 26b.
1. The bond wires 26a of the first subset are electrically coupled between a first set of bond pads on the die 12 and a first set of contact points 22 on the substrate 16 respectively. The first subset of wire bonds 26a are formed by ball bonds 28 formed on the first subset of bond pads on the die 12 and stitch bonds 30 formed on the first subset of contact points 22 respectively. The ball bonds are designated by an “•” and the stitch bonds are designated by an “x” in the figures.
2. Alternatively, the second subset of bond wires 26b of the selected subject are electrically coupled between a second set of bond pads on the die 12 and a second set of contact points 22 on the substrate 16. The second subset of wire bonds 26b are formed by stitch bonds 30 formed on the second subset of bond pads on the die 12 and ball bonds 28 formed on the second subset of contact points 22 on the substrate 16 respectively. Again, the ball bonds are designated by an “•” and the stitch bonds are designated by an “x” in the figures

As is evident in FIG. 1, the first set of wire bonds 26a and the second set of wire bonds 26b have different height profiles. The height profile of the first set of wire bonds 26a are higher relative to the second set of wire bonds 26b. The different height profile tends to reduce signal noise and cross talk between the bond wires 26.

Referring to FIG. 2, a top view of the package 10 is shown. In this view, the die 12 is shown mounted onto the die attach area (not visible) in the center and the plurality of contact points 22 are arranged around the periphery of the substrate 16. In one embodiment, the individual wire bonds of the first subset of wire bond 26a and the second subset of wire bonds 26b are arranged adjacent to one another respectively. In other words, each bond wire 26a is “sandwiched” between two adjacent bond wires 26b and vice versa. Again, the different height profiles of the adjacent wire bonds 26 tends to reduce signal noise and cross talk between the wires.

Although the foregoing invention has been described in some detail for purposes of clarity of understanding, it will be apparent that certain changes and modifications may be practiced within the scope of the appended claims. For example, the substrate 14 and described herein can be made of a number of different materials, such as ceramic or plastic. The substrate 14 can also be a lead frame made of a metal such as copper. In embodiments where the substrate 16 is a lead frame, the die 12 is attached to the die attach pad and the contact pads 22 are leads of the lead frame. Therefore, the described embodiments should be taken as illustrative and not restrictive, and the invention should not be limited to the details given herein but should be defined by the following claims and their full scope of equivalents.

We claim:

1. An semiconductor package, comprising;
a semiconductor die having a plurality of bond pads formed thereon, the bond pads arranged in a first subset of bond pads and a second subset of bond pads;
a substrate having a die attach area and a plurality of contact points, the plurality of contact points arranged in a first subset of contact points and a second subset of contact points;
a first subset of wire bonds electrically coupled between the first subset of bond pads and the first subset of the contact points, the first subset of wire bonds having ball bonds formed on the first subset of bond pads and stitch bonds formed on the first subset of contact points respectively; and
a second subset of wire bonds electrically coupled between the second subset of bond pads and the second subset of the contact points, the second subset of wire bonds having stitch bonds formed on the first subset of bond pads and ball bonds formed on the first subset of contact points respectively.

2. The package of claim 1, wherein the first subset of wire bonds has a first height profile.

3. The package of claim 2, wherein the second subset of wire bonds has a second height profile, the first height profile being different than the second height profile.

4. The package of claim 1, wherein the height profile of the first subset of wire bonds is higher relative to the height profile of the second subset of wire bonds.

5. The package of claim 1, wherein individual wire bonds of the first subset of wire bond and the second subset of wire bonds are arranged adjacent to one another respectively.

6. The package of claim 1, wherein individual wire bonds of the first subset of wire bond and the second subset of wire bonds are arranged in an alternating pattern respectively.

7. The package of claim 1, wherein the substrate is a lead frame and the contact points are leads on the lead frame.

8. A method of making a semiconductor package, comprising;
providing a die on a die attach area of a substrate,
the die having a plurality of bond pads formed thereon, the bond pads arranged in a first subset of bond pads and a second subset of bond pads; and
the substrate having a plurality of contact points, the plurality of contact points arranged in a first subset of contact points and a second subset of contact points;
forming a first subset of wire bonds electrically coupled between the first subset of bond pads and the first subset of the contact points, the first subset of wire bonds formed by:
forming ball bonds on the first subset of bond pads; and
forming stitch bonds on the first subset of contact points respectively; and
forming a second subset of wire bonds electrically coupled between the second subset of bond pads and the second subset of the contact points, the second subset of wire bonds formed by:
forming stitch bonds on the second subset of bond pads; and
forming ball bonds on the first subset of contact points respectively.

9. The method of claim 8, wherein the first subset of wire bonds has a first height profile.

10. The method of claim 9, wherein the second subset of wire bonds has a second height profile, the first height profile being different than the second height profile.

11. The method of claim 8, wherein the height profile of the first subset of wire bonds is higher relative to the height profile of the second subset of wire bonds.

12. The method of claim 8, further arranging the individual wire bonds of the first subset of wire bond and the second subset of wire bonds in an alternating pattern respectively.

13. The method of claim 8, wherein the substrate is a lead frame and the contact points are leads on the lead frame.
